(19) United States
(12) Patent Application Publication
(10) Pub. No.: US 2026/0354157 A1
(43) Pub. Date: Nov. 5, 2026

(54) SEMICONDUCTOR DEVICE INCLUDING METAL PLUG WITH ROUNDED TOP SURFACE AND METHOD OF MAUNFACTURING THE SAME

(71) Applicant: NANYA TECHNOLOGY CORPORATION, NEW TAIPEI CITY (TW)

(72) Inventor: PING HSU, NEW TAIPEI CITY (TW)

(21) Appl. No.: 19/214,508

(22) Filed: May 21, 2025

Related U.S. Application Data
(63) Continuation of application No. 19/194,406, filed on Apr. 30, 2025.

(51) Int. Cl. H10W 20/43

(52) U.S. Cl. CPC H10W 20/43

(57) ABSTRACT

The present disclosure provides a semiconductor device including a metal plug with rounded top surface and a method for manufacturing the semiconductor device. The semiconductor device includes a semiconductor substrate, a first dielectric layer, an etch stop layer, and a second dielectric layer sequentially disposed over the semiconductor substrate, and a first metal plug disposed penetrating through the second dielectric layer, the etch stop layer, and the first dielectric layer. The first metal plug protrudes from the second dielectric layer. The first metal plug has a convex top surface. In addition, the semiconductor device also includes a second metal plug disposed over the first metal plug.

### CROSS-REFERENCE TO RELATED APPLICATION

This application is a continuation application of U.S. Non-Provisional application Ser. No. 19/194,406 filed Apr. 30, 2025, which is incorporated herein by reference in its entirety.

### TECHNICAL FIELD

The present disclosure relates to a semiconductor device and a method for manufacturing the semiconductor device, and more particularly, to a semiconductor device including a metal plug with rounded top surface and a method for manufacturing the semiconductor device.

### DISCUSSION OF THE BACKGROUND

Semiconductor devices are essential for many modern applications. With advancement of electronic technology, semiconductor devices are becoming smaller in size while providing greater functionality and including greater amounts of integrated circuitry. Due to the miniaturized scale of semiconductor devices, distinct types and dimensions of semiconductor devices providing different functionalities are integrated and packaged into a single module. Furthermore, numerous manufacturing operations are implemented for integration of such distinct types of semiconductor devices.

However, the manufacturing and integration of semiconductor devices involve many complicated steps and operations. Integration in semiconductor devices becomes increasingly complicated. An increase in complexity of manufacturing and integration of the semiconductor device may cause deficiencies, such as short circuit and leakage current between neighboring conductive features. Accordingly, there is a continuous need to improve the manufacturing process of semiconductor devices so that the problems can be addressed.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device. The semiconductor device includes a substrate having a pattern-dense region and a pattern-sparse region; a first dielectric layer disposed over the semiconductor substrate; an etch stop layer disposed over the first dielectric layer; a second dielectric layer disposed over the etch stop layer; a first metal plug disposed penetrating through the second dielectric layer, the etch stop layer, and the first dielectric layer, wherein the first metal plug comprises a convex top surface; a third dielectric layer disposed covering the second dielectric layer and the convex top surface of the first metal plug; a lining layer disposed within the third dielectric layer, extending over the third dielectric layer, and covering the convex top surface of the first metal plug; a second metal plug disposed over the first metal plug and surrounded by the lining layer; a fourth dielectric layer disposed over the lining layer and the second metal plug; a first conductive feature and a second conductive feature disposed in the fourth dielectric layer and within the pattern-dense region of the substrate; and a third conductive feature disposed in the fourth dielectric layer and within the pattern-sparse region of the substrate. The first metal plug protrudes from the second dielectric layer.

Another aspect of the present disclosure provides a semiconductor device. The semiconductor device includes a substrate having a pattern-dense region and a pattern-sparse region; an etch stop layer disposed over the substrate; a first dielectric layer disposed over the etch stop layer; a first conductive plug and a second conductive plug disposed in the first dielectric layer. The first conductive plug and the second conductive plug comprise copper and are separated from the first dielectric layer by a first lining layer comprising manganese (Mn). The first conductive plug and the second conductive plug have different aspect ratios. The first lining layer extends from the pattern-dense region to the pattern-sparse region and includes a first segment deposited under the first conductive plug and a second segment deposited under the second conductive plug, the first segment of the first lining layer and the second segment of the first lining layer include different thicknesses.

Another aspect of the present disclosure provides a method for manufacturing a semiconductor device. The method includes providing a substrate having a pattern-dense region and a pattern-sparse region; forming a first dielectric layer over the semiconductor substrate; forming an etch stop layer over the first dielectric layer; forming a second dielectric layer over the etch stop layer; forming a first metal plug penetrating through the second dielectric layer, the etch stop layer and the first dielectric layer, wherein the first metal plug protrudes from the second dielectric layer and has a convex top surface; forming a third dielectric layer covering the second dielectric layer and the convex top surface of the etched first metal plug; forming a second metal plug over the first metal plug; forming a fourth dielectric layer over the third dielectric layer and covering the second metal plug; and forming a first conductive feature and a second conductive feature in the fourth dielectric layer and within the pattern-dense region of the substrate, and forming a third conductive feature in the fourth dielectric layer and within the pattern-sparse region of the substrate.

Another aspect of the present disclosure provides a method for manufacturing a semiconductor device. The method includes providing a substrate having a pattern-dense region and a pattern-sparse region; forming an etch stop layer over the substrate; forming a first dielectric layer over the etch stop layer; forming a first conductive plug in the first dielectric layer and within the pattern-dense region; and forming a second conductive plug in the first dielectric layer and within the pattern-sparse region.

Embodiments of a semiconductor device and methods for forming the same are provided. The semiconductor device may include a first metal plug and a second metal plug over the first metal plug. Since the first metal plug has a rounded top surface, the contact area between the first metal plug and the second metal plug is increased, and the electric field strength on the rounded top surface of the first metal plug is evenly distributed. As a result, the performance and reliability of the device may be improved. Moreover, the issues caused by misalignment between the first metal plug and the second metal plug may be prevented or reduced.

The foregoing has outlined rather broadly the features and technical advantages of the present disclosure in order that the detailed description of the disclosure that follows may be better understood. Additional features and advantages of the disclosure are described below, and form the subject of the claims of the disclosure. It should be appreciated by those skilled in the art that the conception and specific embodiments disclosed herein may be readily utilized as a basis for modifying or designing other structures or processes for carrying out the purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a cross-sectional view illustrating a semiconductor device in accordance with some embodiments of the present disclosure.

FIG. 2 is a partially enlarged view of a region A in FIG. 1 in accordance with some embodiments of the present disclosure.

FIG. 3 is a cross-sectional view illustrating a semiconductor device in accordance with various embodiments of the present disclosure.

FIG. 4 is a flow diagram of a method for manufacturing a semiconductor device in accordance with some embodiments of the present disclosure.

FIG. 5 is a cross-sectional view illustrating an intermediate stage in the formation of a photoresist pattern for a semiconductor device in accordance with some embodiments of the present disclosure.

FIG. 6 is a cross-sectional view illustrating an intermediate stage in the formation of openings for a semiconductor device in accordance with some embodiments of the present disclosure.

FIG. 7 is a cross-sectional view illustrating an intermediate stage in the formation of a metal layer for a semiconductor device in accordance with some embodiments of the present disclosure.

FIG. 8 is a cross-sectional view illustrating an intermediate stage in the formation of metal portions for a semiconductor device in accordance with some embodiments of the present disclosure.

FIG. 9 is a cross-sectional view illustrating an intermediate stage in the formation of metal plugs for a semiconductor device in accordance with some embodiments of the present disclosure.

FIG. 10 is a cross-sectional view illustrating an intermediate stage in the formation of metal plugs with rounded top surfaces for a semiconductor device in accordance with some embodiments of the present disclosure.

FIG. 11 is a cross-sectional view illustrating an intermediate stage in the formation of silicide layers for a semiconductor device in accordance with some embodiments of the present disclosure.

FIG. 12 is a cross-sectional view illustrating an intermediate stage in the formation of a dielectric layer for a semiconductor device in accordance with some embodiments of the present disclosure.

FIG. 13 is a cross-sectional view illustrating an intermediate stage in the formation of a photoresist pattern for a semiconductor device in accordance with some embodiments of the present disclosure.

FIG. 14 is a cross-sectional view illustrating an intermediate stage in the formation of openings and gaps for a semiconductor device in accordance with some embodiments of the present disclosure.

FIG. 15 is a cross-sectional view illustrating an intermediate stage in the formation of an energy-removable material for a semiconductor device in accordance with some embodiments of the present disclosure.

FIG. 16 is a cross-sectional view illustrating an intermediate stage in the formation of a metal layer for a semiconductor device in accordance with some embodiments of the present disclosure.

FIG. 17 is a cross-sectional view illustrating an intermediate stage in the formation of energy-removable layers and metal plugs for a semiconductor device in accordance with some embodiments of the present disclosure.

FIG. 18 is a cross-sectional view illustrating an intermediate stage in the formation of a dielectric layer for a semiconductor device in accordance with some embodiments of the present disclosure.

FIG. 19 is a cross-sectional view illustrating an intermediate stage in the formation of metal-insulator-metal capacitors for a semiconductor device in accordance with some embodiments of the present disclosure.

FIG. 20 is a cross-sectional view illustrating an intermediate stage in the formation of a lining layer for a semiconductor device in accordance with various embodiments of the present disclosure.

FIG. 21 is a cross-sectional view illustrating an intermediate stage in the formation of conductive features and a liner structure for a semiconductor device in accordance with various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

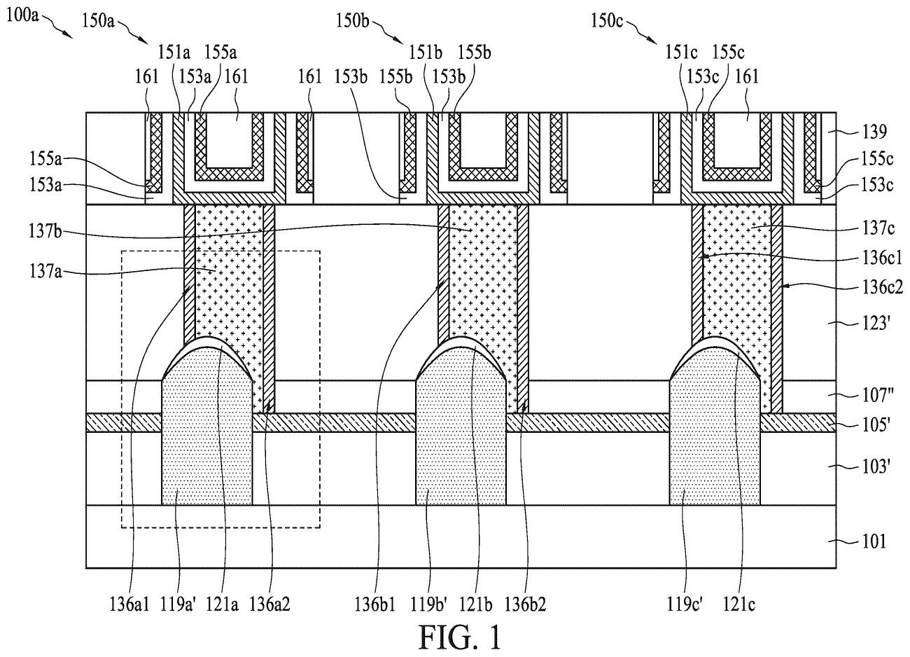

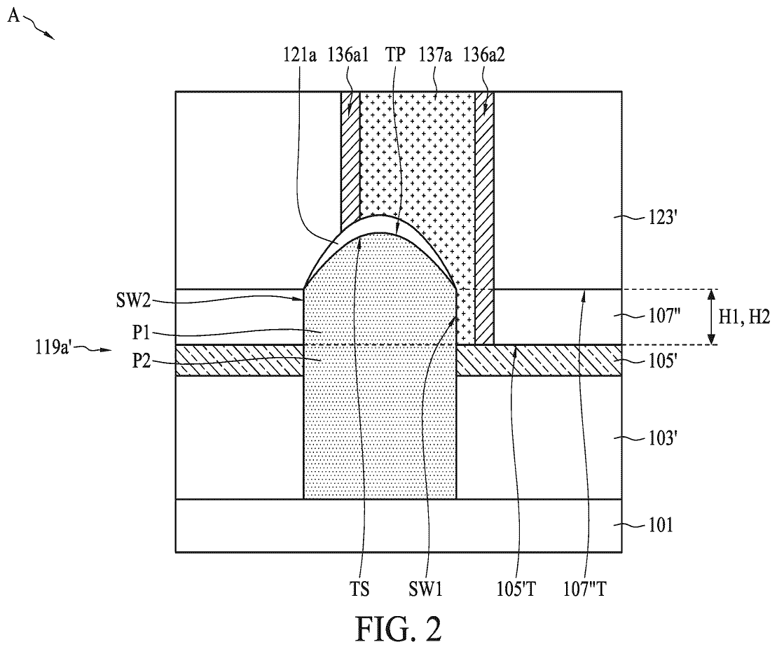

FIG. 1 is a cross-sectional view illustrating a semiconductor device 100a in accordance with some embodiments of the present disclosure, and FIG. 2 is a partially enlarged view of a region A in the semiconductor device 100a.

Referring to FIGS. 1 and 2, the semiconductor device 100a may include a first dielectric layer 103′ and a plurality of first metal plugs 119a′, 119b′, and 119c′ disposed over a semiconductor substrate 101. In addition, in some embodiments, an etch stop layer 105′ may be positioned over the first dielectric layer 103′, and the first metal plugs 119a′, 119b′ and 119c′ may protrude from the etch stop layer 105′.

It should be noted that, although only three first metal plugs are illustrated in FIG. 1, the present disclosure is not limited thereto. Depending on product requirements, a number of the first metal plugs in the semiconductor device structure 100a may be fewer or greater than three. Referring to FIG. 2, the first metal plug 119a′ has an upper portion P1 protruding from a top surface 105′T of the etch stop layer 105′, and a lower portion P2 beneath the upper portion P1.

In some embodiments, the etch stop layer 105′ and the first dielectric layer 103′ surround the lower portion P2 of the first metal plug 119a′, and the upper portion P1 of the first metal plug 119a′ has a rounded (or curved) top surface TS. In some embodiments, the etch stop layer 105′ and the first dielectric layer 103′ may adjoin the sidewalls of the lower portion P2. Additionally, in some embodiments, a top surface TS of the upper portion P1 is convex, and the top surface TS may be located between a first sidewall SW1 and a second sidewall SW2 of the upper portion P1.

Moreover, as shown in FIG. 1, the semiconductor device 100a may include a plurality of second metal plugs 137a, 137b, and 137c disposed over the first metal plugs 119a′, 119b′, and 119c′, a second dielectric layer 107″ disposed over the etch stop layer 105′, and a third dielectric layer 123′ disposed over the second dielectric layer 107″. In the present embodiment, the semiconductor device 100a includes a plurality of silicide layers 121a, 121b, and 121c disposed between the first metal plugs 119a′, 119b′, and 119c′ and the second metal plugs 137a, 137b, and 137c. By forming the silicide layers 121a, 121b, and 121c, the contact resistance between the first metal plugs 119a′, 119b′, and 119c′ and the second metal plugs 137a, 137b, and 137c may be decreased, thereby improving the performance of the semiconductor device 100a. However, in some other embodiments, the silicide layers 121a, 121b, and 121c can be omitted.

Referring to FIG. 2, in accordance with some embodiments, the second metal plug 137 a may extend to contact the top surface 105′T of the etch stop layer 105′. The first sidewall SW1 of the upper portion P1 of the first metal plug 119a′ is in direct contact with the second metal plug 137a, while the second sidewall SW2 of the upper portion P1 of the first metal plug 119a′ is in direct contact with the second dielectric layer 107″.

It should be noted that the second dielectric layer 107″ may be separated from the first sidewall SW1, and a height H1 of the first sidewall SW1 may be substantially same as a height H2 of the second dielectric layer 107″. Within the context of this disclosure, the word “substantially” means preferably at least 90%, more preferably 95%, even more preferably 98%, and most preferably 99%.

In some embodiments, the top surface TS of the upper portion P1 of the first metal plug 119a′ may have a topmost point TP. This topmost point TP may be higher than the top surface 107″T of the second dielectric layer 107″. In other words, the upper portion P1 of the first metal plug 119 a′ protrudes from the top surface 107″T of the second dielectric layer 107″.

In addition, the top surface TS of the upper portion P1 of the first metal plug 119a′ may be separated from the second metal plug 137a by the silicide layer 121a, which extends between the top surface TS and the third dielectric layer 123′. In other words, the third dielectric layer 123′ may partially cover the upper portion P1 of the first metal plug 119a′.

The second metal plugs 137a, 137b, and 137c may be separated from the second dielectric layer 123′ by a plurality of air gaps 136a1, 136a2, 136b1, 136b2, 136c1, and 136c2, as shown in FIGS. 1 and 2 in accordance with some embodiments. By forming the air gaps 136a1, 136a2, 136b1, 136b2, 136c1, and 136c2, a parasitic capacitance between adjacent second metal plugs may be reduced, thereby improving operation speed of the semiconductor device 100a. However, in some embodiments, the air gaps 136a1, 136a2, 136b1, 136b2, 136c1, and 136c2 can be omitted.

It should be noted that the aforementioned features of the region A in the semiconductor device 100a are similar to, or same as, features of other regions in the semiconductor device 100a, such as the region including the first metal plug 119b′ or the region including the first metal plug 119c′.

Referring to FIG. 1, the semiconductor device 100a may further include a plurality of metal-insulator-metal (MIM) capacitors 150a, 150b, and 150c disposed over the second metal plugs 137a, 137b, and 137c, a fourth dielectric layer 139 surrounding the MIM capacitors 150a, 150b, and 150c, and a filling dielectric layer 161 that may fill the space within the MIM capacitors 150a, 150b, and 150c, in accordance with some embodiments. It should be noted that the MIM capacitors 150a, 150b, and 150c are electrically connected to the first metal plugs 119a′, 119b′, and 119c′ through the second metal plugs 137a, 137b, and 137c, in accordance with some embodiments.

Specifically, in some embodiments, the MIM capacitor 150a may include a metal layer 151a, an insulating layer 153a, and a metal layer 155a. Similarly, the MIM capacitor 150b may include a metal layer 151b, an insulating layer 153b, and a metal layer 155b, while the MIM capacitor 150c may include a metal layer 151c, an insulating layer 153c, and a metal layer 155c.

In some embodiments, the metal layer 151a may have a U-shaped profile, and the second metal plug 137a may be covered by the metal layer 151a. Moreover, the metal layer 151a may be surrounded by the insulating layer 153a, and the insulating layer 153a may be surrounded by the metal layer 155a, as shown in FIG. 1. The details of the metal and insulating layers in the MIM capacitors 150b and 150c are similar to, or same as, those of the MIM capacitor 150a, and descriptions thereof are not repeated.

In some embodiments, the filling dielectric layer 161 may fill the space within each of the MIM capacitors 150a, 150b, and 150c, and the MIM capacitors 150a, 150b, and 150c may be separated from each other by the fourth dielectric layer 139. In some embodiments, the semiconductor device 100a is a dynamic random-access memory (DRAM).

In the semiconductor device 100a, since the first metal plugs 119a′, 119b′, and 119c′ have rounded top surfaces, which increase contact areas between the first metal plugs 119a′, 119b′, and 119c′ and the second metal plugs 137a, 137b, and 137c (or between the silicide layers 121a, 121b, and 121c and the second metal plugs 137a, 137b, and 137c), compared to arrangements where the first metal plugs 119a′, 119b′, and 119c′ have flat top surfaces and the second metal plugs 137a, 137b, and 137c are perfectly aligned with the first metal plugs 119a′, 119b′, and 119c′. The rounded top surfaces of the first metal plugs 119a′, 119b′, and 119c′ may also lead to a corresponding decrease in the resistances between the first metal plugs 119a′, 119b′, and 119c′ and the second metal plugs 137a, 137b, and 137c, thereby improving overall device performance.

Moreover, the electric field strengths on the rounded top surfaces of the first metal plugs 119a′, 119b′, and 119c′ are evenly distributed, as the first metal plugs 119a′, 119b′, and 119c′ have no sharp portions. Therefore, the lifespan of the semiconductor device 100a may be extended significantly, and performance and reliability of the device may be improved. Furthermore, since the etch stop layer 105′ adjoins the sidewalls of the first metal plugs 119a′, 119b′, and 119c′, underlying electronic components can be protected from exposure during the formation of the second metal plugs 137a, 137b, and 137c, thereby preventing or reducing issues caused by misalignment between the first metal plugs 119a′, 119b′, and 119c′ and the second metal plugs 137a, 137b, and 137c.

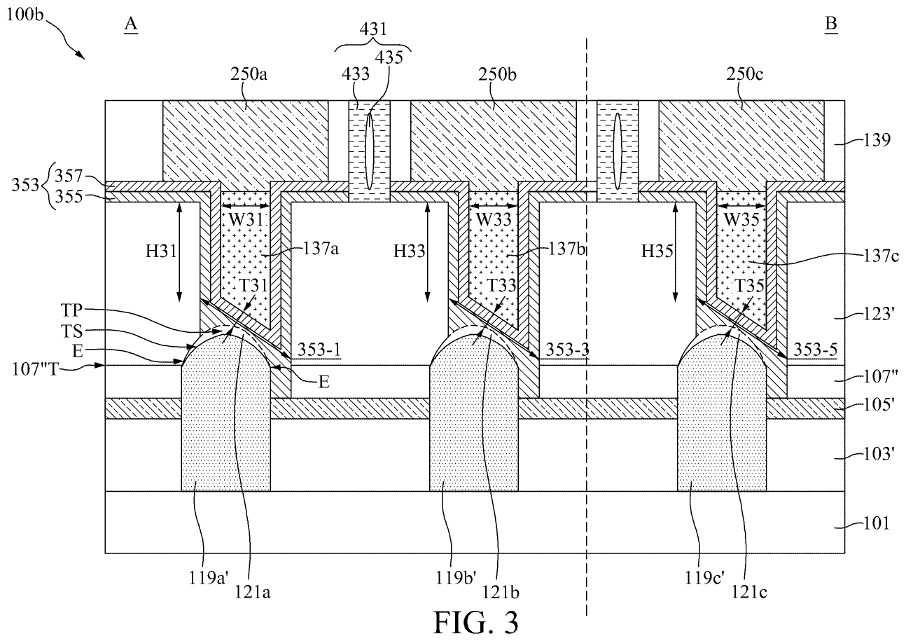

FIG. 3 is a cross-sectional view illustrating a semiconductor device 100b in accordance with various embodiments of the present disclosure. The semiconductor 100b in FIG. 3 is similar to the semiconductor 100a in FIG. 1, and the differences are described below.

The semiconductor 100b may comprise a pattern-dense region A and a pattern-sparse region B. The pattern-dense region A may be referred to as an area where features, such as transistors, interconnects, or other components, are closely packed together with high precision. The pattern-sparse region B may be referred to as an area where the patterning of features is less precise or has a lower density compared to the pattern-dense region.

The second metal plugs 137a, 137b, and 137c of the semiconductor 100b may be disposed in different regions (e.g., the pattern-dense region A and the pattern-sparse region B), surrounded by a lining layer 353. For example, as shown in FIG. 3, the second metal plugs 137a and 137b may be located within the pattern-dense region A, while the second metal plugs 137c may be located within the pattern-sparse region B.

In some embodiments, the second metal plugs 137a and 137b in the pattern-dense region A may have a same aspect ratio, while the second metal plugs 137a and 137c in different region (e.g., the pattern-dense region A and the pattern-sparse region B) may feature different aspect ratios. For example, a ratio of a height H31 of the second metal plug 137a to a width W31 of the second metal plug 137a may be equal to a ratio of a height H33 of the second metal plug 137b to a width W33 of the second metal plug 137b. In another example, the ratio of the height H31 of the second metal plug 137a to the width W31 of the second metal plug 137a may be less than or greater than a ratio of a height H35 of the second metal plug 137c to a width W35 of the second metal plug 137c.

The lining layer 353 of the semiconductor 100b may be a multi-layered structure and may include a first sub-lining layer 355 and a second sub-lining layer 357 disposed over the first sub-lining layer 355. In some embodiments, the lining layer 353 may be disposed within the third dielectric layer 123′, extending over the third dielectric layer 123′, and covering the convex top surface TS of the first metal plugs 119a′, 119b′, and 119c′. In some embodiments, the lining layer 353 may extend from the pattern-dense region A to the pattern-sparse region B and may include a segment 353-1 deposited under the second metal plug 137a, a segment 353-3 under the second metal plug 137b, and a segment 353-5 under the second metal plug 137c. In some embodiments, a thickness T31 of the segment 353-1 may be equal to a thickness T33 of the segment 353-3. In some embodiments, the thickness T31 of the segment 353-1 may be less than or greater than a thickness T35 of the segment 353-5.

In some embodiments, the first sub-lining layer 355 of the lining layer 353 includes manganese-rich manganese silicon (MnSi) or manganese (Mn), and the second sub-lining layer 357 of the lining layer 353 includes copper manganese (CuMn).

The semiconductor 100b may comprise a plurality of conductive features 250a, 250b, and 250c disposed in the fourth dielectric layer 139. The conductive features 250a, 250b, and 250c may be positioned over the second metal plugs 137a, 137b, and 137c, respectively. In some embodiments, the conductive features 250a and 250b, which are located in the pattern-dense region A, may serve as bit lines. The conductive feature 250c, located in the pattern-loose region B, may be a word line, a test point, a connection terminal, or another electrical connection line, such as a power or ground line. It should be noted that the conductive features 250a, 250b, and 250c are electrically connected to the first metal plugs 119a′, 119b′, and 119c′ through the second metal plugs 137a, 137b, and 137c, respectively.

The semiconductor 100b may comprise a liner structure 431 disposed in the fourth dielectric layer 139, positioned between the conductive feature 250a and the conductive feature 250b, as well as between the conductive feature 250b and the conductive feature 250c. In some embodiments, the liner structure 431 may penetrate through the fourth dielectric layer 139 and the lining layer 353. The liner structure 431 may comprise an air gap 435 enclosed by a liner portion 433. In some embodiments, the liner portion 433 is made of or includes boron carbonitride (BCN). However, any other suitable dielectric materials may be utilized. In some embodiments, the air gap 435 is sealed within the liner portion 433, meaning that the air gap 435 is not exposed.

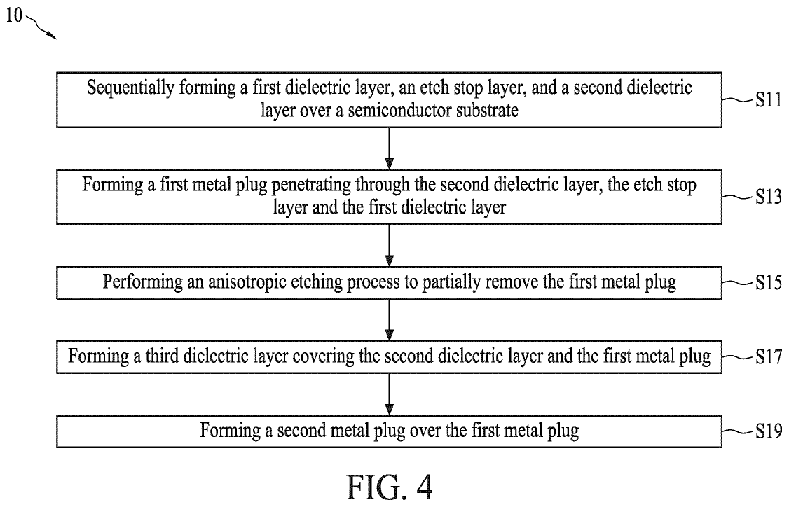

FIG. 4 is a flow diagram of a method 10 for manufacturing the semiconductor device 100a or 100. In accordance with some embodiments of the present disclosure, the method 10 may include steps S11, S13, S15, S17, and S19. The steps S11 to S19 in FIG. 4 are elaborated upon in connection with other figures of the present disclosure, which are cross-sectional views illustrating sequential intermediate stages in the formation of the semiconductor device 100a or 100b.

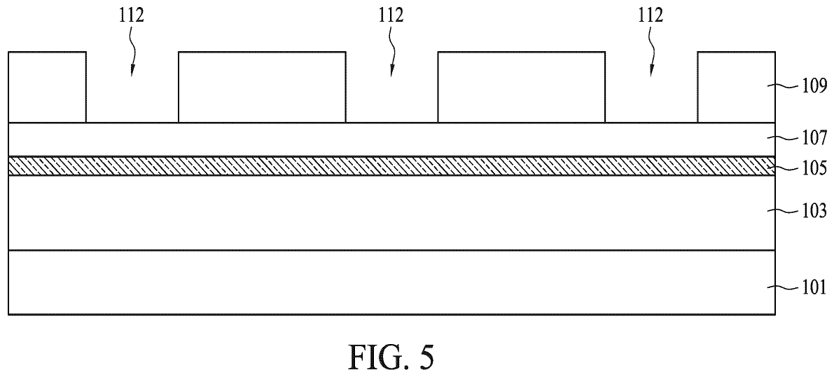

As shown in FIG. 5, the semiconductor substrate 101 is provided. The semiconductor substrate 101 may be a portion of an integrated circuit (IC) chip that includes various passive and active microelectronic devices, such as resistors, capacitors, inductors, diodes, p-type field-effect transistors (pFETs), n-type field-effect transistors (nFETs), metal-oxide semiconductor field-effect transistors (MOSFETs), complementary metal-oxide semiconductor (CMOS) transistors, bipolar junction transistors (BJTs), laterally diffused MOS (LDMOS) transistors, high voltage transistors, high frequency transistors, fin field-effect transistors (FinFETs), other suitable IC components, or combinations thereof.

Depending on the IC fabrication stage, the semiconductor substrate 101 may include various material layers (e.g., dielectric layers, semiconductor layers, and/or conductive layers) configured to form IC features (e.g., doped regions, isolation features, gate features, source/drain features, interconnect features, other features, or combinations thereof). The semiconductor substrate 101 has been simplified for the sake of clarity. It should be noted that additional features can be added in the semiconductor substrate 101, and some of the features described below can be replaced, modified, or eliminated in other embodiments.

In some embodiments, the first dielectric layer 103, the etch stop layer 105, and the second dielectric layer 107 are sequentially disposed over the semiconductor substrate 101. The respective step is illustrated as the step S11 in the method 10 shown in FIG. 4.

In some embodiments, the first dielectric layer 103 may be made of silicon oxide, silicon carbide, silicon nitride, silicon oxynitride, another suitable material, or a combination thereof, and the first dielectric layer 103 may be formed using a deposition process, such as a chemical vapor deposition (CVD) process, a physical vapor deposition (PVD) process, an atomic layer deposition (ALD) process, a spin-on process, or another suitable process.

Some materials and processes used to form the etch stop layer 105 and the second dielectric layer 107 are similar to, or the same as, those used to form the first dielectric layer 103, and descriptions thereof are not repeated herein. It should be noted that the material of the etch stop layer 105 is different from the material of the second dielectric layer 107, in accordance with some embodiments.

After the second dielectric layer 107 is formed, a photoresist pattern 109 with openings 112 may be disposed over the second dielectric layer 107, and the second dielectric layer 107 may be exposed by the openings 112, as shown in FIG. 5. In some embodiments, the photoresist pattern 109 may be formed using a deposition process and a patterning process.

The deposition process for forming the photoresist pattern 109 may include a CVD process, a high-density plasma chemical vapor deposition (HDPCVD) process, a spin-on process, or another suitable process. The patterning process for forming the photoresist pattern 109 may include a photolithography process. The photolithography process may include photoresist coating (e.g., spin coating), soft baking, mask aligning, exposure, post-exposure baking, developing the photoresist, rinsing and drying (e.g., hard baking).

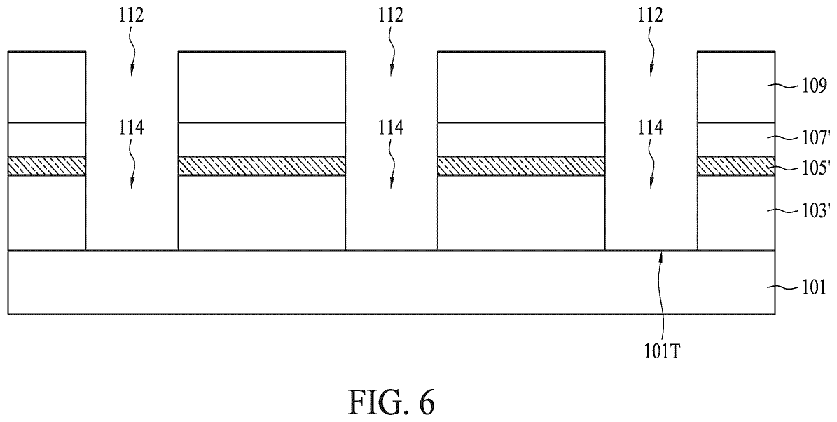

Next, as shown in FIG. 6, an etching process may be performed on the structure using the photoresist pattern 109 as a mask. It should be noted that the etching process is performed until a top surface 101T of the semiconductor substrate 101 is exposed, and openings 114 are formed under the openings 112.

After the etching process, the openings 114 are surrounded by the remaining second dielectric layer 107′, the remaining etch stop layer 105′ and the remaining first dielectric layer 103′. The etching process may be a dry etching process, a wet etching process, or a combination thereof.

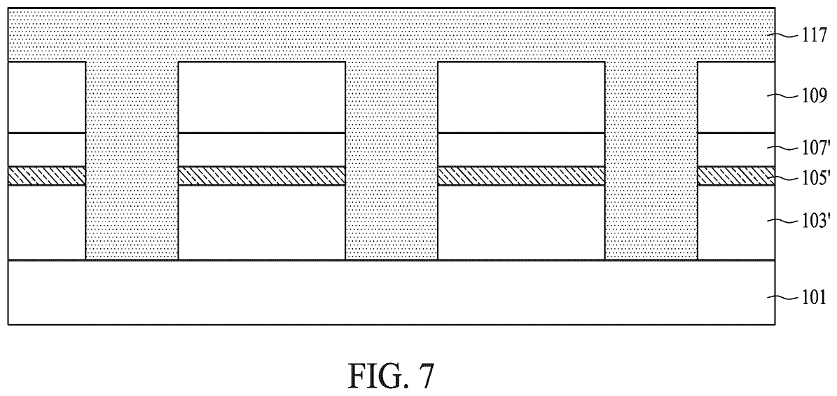

After the openings 114 are formed, a metal layer 117 may be deposited to fill the openings 114, as shown in FIG. 7. Specifically, the openings 114 may be completely filled with the metal layer 117, and the metal layer 117 may also extend onto the photoresist pattern 109.

The metal layer 117 may be made of copper (Cu). In some embodiments, the metal layer 117 is made of tungsten (W), cobalt (Co), titanium (Ti), aluminum (Al), tantalum (Ta), or another applicable material. Moreover, in some embodiments, the metal layer 117 may be formed using a CVD process, a PVD process, an ALD process, a plating (e.g., electroplating) process, a sputtering process, or another suitable process.

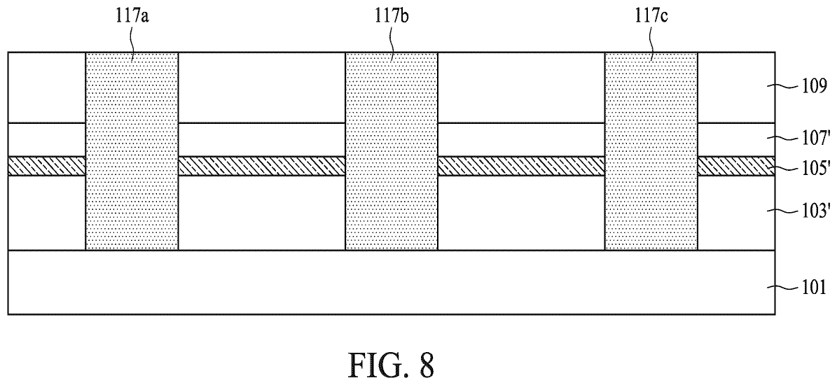

Next, in accordance with some embodiments, excess portions of the metal layer 117 may be removed to form metal portions 117a, 117b, and 117c, as shown in FIG. 8. Specifically, the portions of the metal layer 117 covering the photoresist pattern 109 may be removed, while the portions of the metal layer 117 deposited in the openings 112 and 114 are left in place.

In some embodiments, the removal of the excess portions of the metal layer 117 is performed using a planarization process or an etching process. The planarization process may be a chemical mechanical polishing (CMP) process.

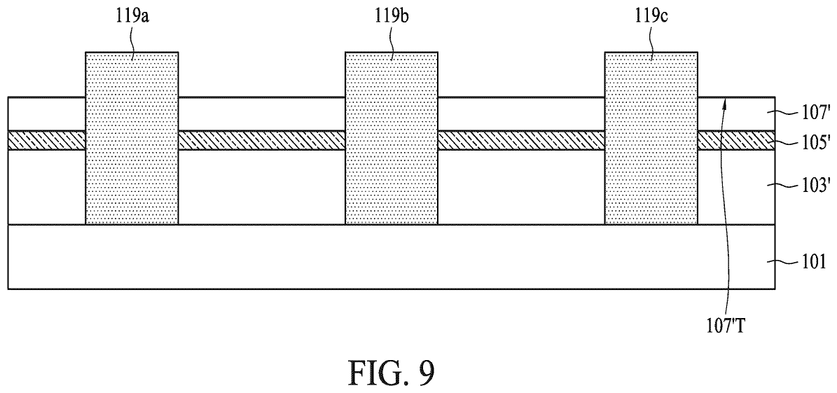

After the metal portions 117a, 117b, and 117c are formed, the photoresist pattern 109 may be removed, as shown in FIG. 9. In some embodiments, during the removal process of the photoresist pattern 109, the portions of the metal portions 117a, 117b, and 117c protruding from a top surface 107′T of the second dielectric layer 107′ may be slightly etched. As a result, first metal plugs 119a, 119b, and 119c can be obtained (i.e., the remaining metal portions 117a, 117b, and 117c).

In particular, in accordance with some embodiments of the present disclosure, each of the first metal plugs 119a, 119b, and 119c may penetrate through the second dielectric layer 107′, the etch stop layer 105′, and the first dielectric layer 103′ to electrically connect to the electronic components in the semiconductor substrate 101. The respective step is illustrated as the step S13 in the method 10 shown in FIG. 4. It should be noted that the first metal plugs 119a, 119b, and 119c still protrude from the top surface 107′T of the second dielectric layer 107′.

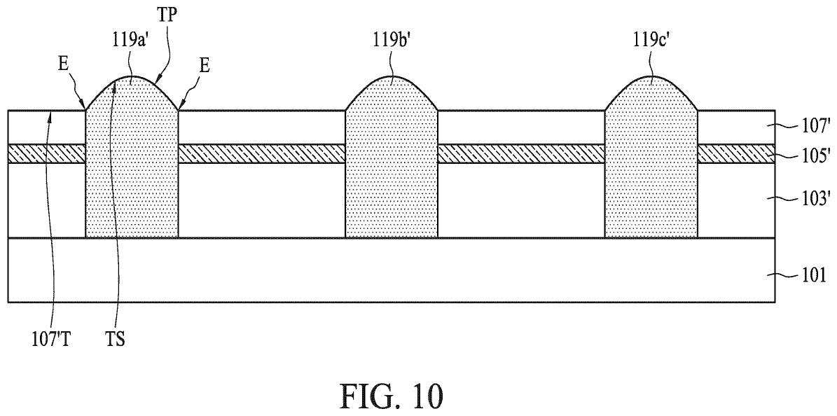

An anisotropic etching process may be performed to partially remove the first metal plugs 119a, 119b, and 119c, such that each of the etched first metal plugs 119a′, 119b′, and 119c′ has a rounded (or curved) top surface TS, as illustrated in FIG. 10. In some embodiments, the top surfaces TS of the first metal plugs 119a′, 119b′, and 119c′ are convex. The respective step is illustrated as the step S15 in the method 10 shown in FIG. 4.

As mentioned above, the topmost points TP of the top surfaces TS of the first metal plugs 119a′, 119b′, and 119c′ may be higher than the top surface 107′T of the second dielectric layer 107′. Specifically, in accordance with some embodiments, the edges E of the top surfaces TS are in direct contact with the top surface 107′T of the second dielectric layer 107′. For simplicity and clarity, the top surfaces TS, the topmost points TP and the edges E are indicated only in the first metal plug 119a′ in FIG. 10. However, the first metal plugs 119b′ and 119c′ in FIG. 10 may have features similar to those of the first metal plug 119a′. In some embodiments, the anisotropic etching process is a dry etching process.

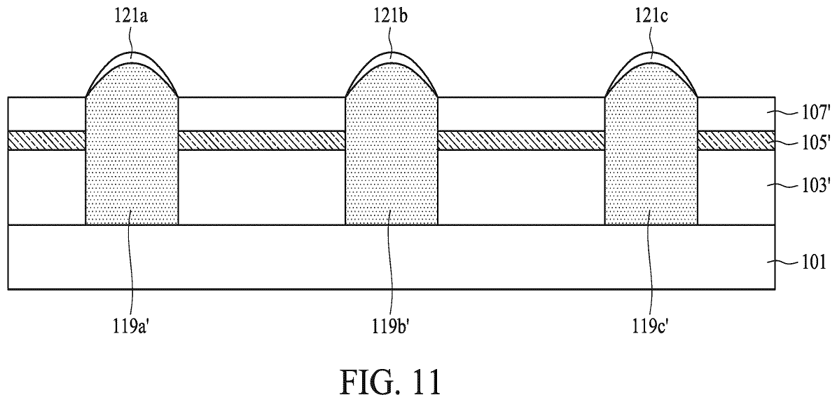

Next, in accordance with some embodiments, silicide layers 121a, 121b, and 121c may be disposed over the first metal plugs 119a′, 119b′ and 119c′ using a silicidation process, as shown in FIG. 11. In some embodiments, the silicidation process may include a metal material deposition process followed by an annealing process performed. In some embodiments, the deposition process of the silicidation process may involve a PVD process, an ALD process, or another suitable process. After the annealing process, the unreacted metal material is removed.

In some embodiments, the silicide layers 121a, 121b, and 121c may be made of one of more of the following materials: copper silicide, tungsten silicide, cobalt silicide, titanium silicide, nickel silicide, and molybdenum silicide. As mentioned above, by forming the silicide layers 121a, 121b, and 121c, a contact resistance between the first metal plugs 119a′, 119b′, and 119c′ and the overlying conductive components (e.g., the second metal plugs 137a, 137b, and 137c, as shown in FIGS. 1 and 3) may be decreased, thereby improving a performance of the device. In some other embodiments, the silicidation process is not performed and the silicide layers 121a, 121b, and 121c are not formed.

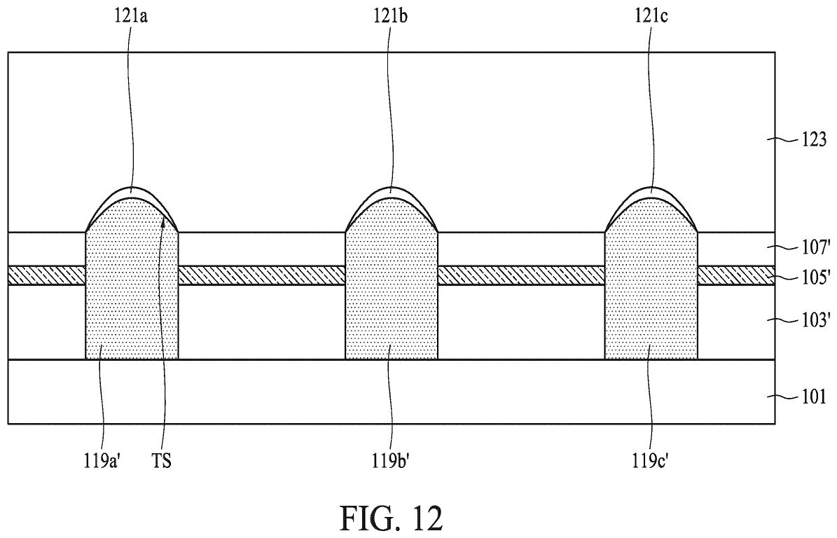

As shown in FIG. 12, in accordance with some embodiments, the third dielectric layer 123 may be formed to cover the second dielectric layer 107′ and the first metal plugs 119a′, 119b′, and 119c′. The respective step is illustrated as the step S17 in the method 10 shown in FIG. 4. In some embodiments, the silicide layers 121a, 121b, and 121c are covered by the third dielectric layer 123.

It should be noted that, in accordance with some embodiments the top surfaces TS of the first metal plugs 119a′, 119b′, and 119c′ may be separated from the third dielectric layer 123 by the silicide layers 121a, 121b, and 121c. Some materials and processes used to form the third dielectric layer 123 are similar to, or the same as, those used to form the first dielectric layer 103, and descriptions thereof are not repeated. Additionally, it should also be noted that the material of the third dielectric layer 123 is different from that of the etch stop layer 105′.

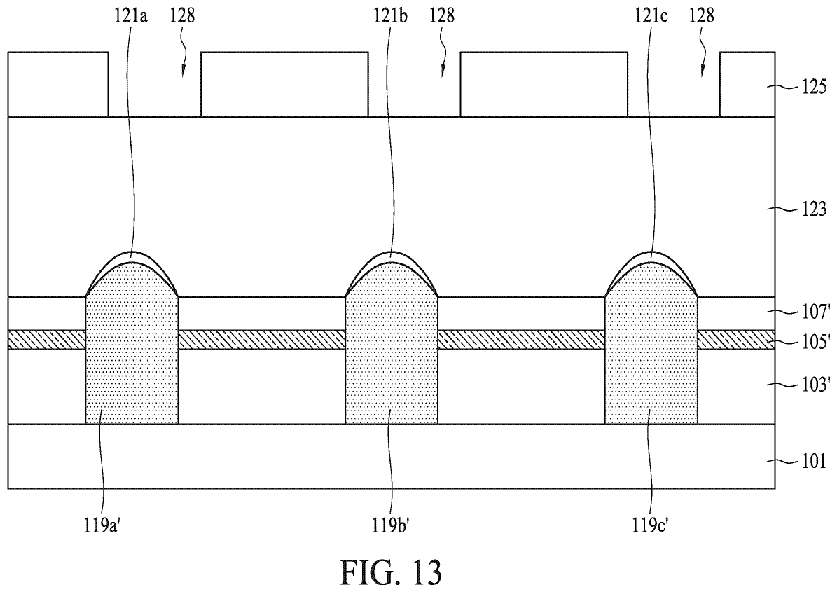

After the third dielectric layer 123 is formed a photoresist pattern 125 with openings 128 may be disposed over the third dielectric layer 123, as shown in FIG. 13. The openings 128 may expose he third dielectric layer 123. Some materials and processes used to form the photoresist pattern 125 are similar to, or the same as, those used to form the photoresist pattern 109 in FIG. 5, and descriptions thereof are not repeated.

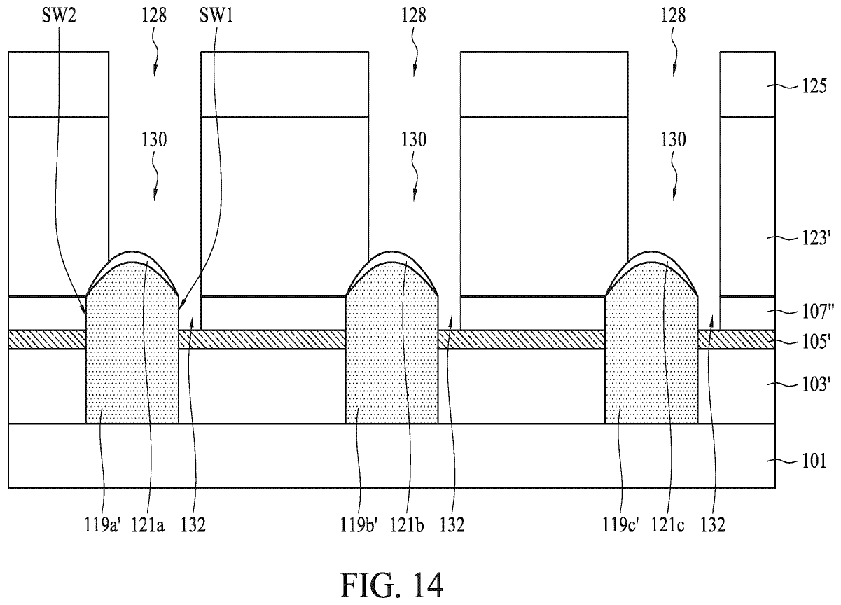

Next, an etching process may be performed on the structure using the photoresist pattern 125 as a mask, as shown in FIG. 14. It should be noted that the etching process may be performed until the silicide layers 121a, 121b, and 121c or the first metal plugs 119a′, 119b′, and 119c′ are exposed, resulting in openings 130 are formed in the remaining third dielectric layer 123′ and gaps 132 in the remaining second dielectric layer 107″. In addition, the etching process may be a dry etching process, a wet etching process, or a combination thereof.

In some embodiments, during the etching process, the positions of the openings 128 over the second dielectric layer 107′ (see FIG. 13) may cause the openings 130 to expose portions of the second dielectric layer 107′, and the exposed portions of the second dielectric layer 107′ may then be removed to form the gaps 132. It should be noted that the top surface 105′T of the etch stop layer 105′ is exposed by the gaps 132, in accordance with some embodiments. As mentioned above, the etch stop layer 105′ can protect the underlying electronic components from exposure during the etching process.

Moreover, each of the first metal plugs 119a′, 119b′, and 119c′ has a first sidewall SW1 and a second sidewall SW2 opposite to the first sidewall SW1. In some embodiments, the first sidewalls SW1 may be exposed by the gaps 132, and the second sidewalls SW2 may be covered by the second dielectric layer 107″. After the openings 130 and the gaps 132 are formed, portions of the silicide layers 121a, 121b, and 121c are sandwiched between the third dielectric layer 123′ and the first metal plugs 119a′, 119b′, and 119c′.

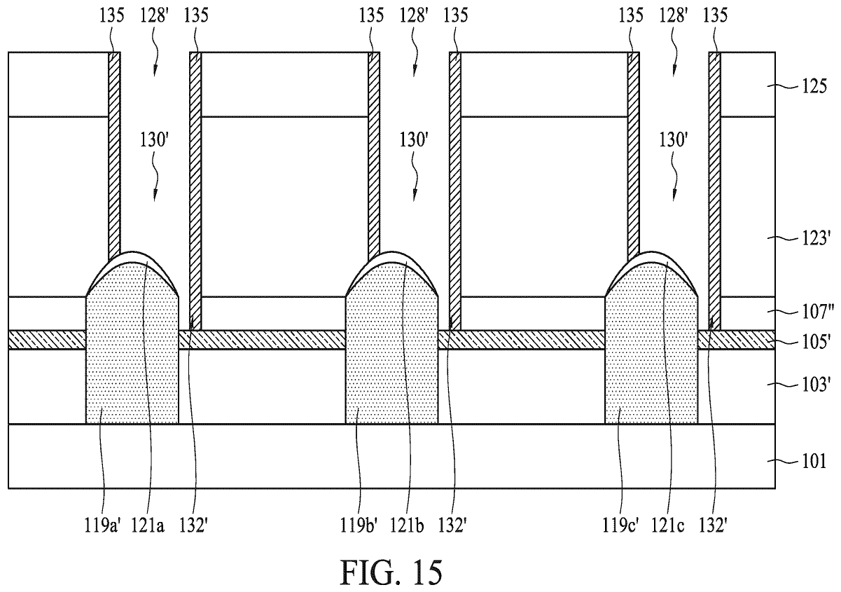

In accordance with some embodiments, an energy-removable material 135 may be disposed over sidewalls of the openings 128 and 130, as well as the gaps 132 in FIG. 14, resulting in reduced openings 128′ and 130′ and reduced gaps 132′, as shown in FIG. 15.

In some embodiments, the energy-removable material 135 may include a thermal-decomposable material. In some other embodiments, the energy-removable material 135 includes a photonic-decomposable material, an e-beam decomposable material, or another suitable energy-decomposable material. Specifically, the energy-removable material 135 may consist of a base material and a decomposable porogen material that is substantially removed upon exposure to an energy source (e.g., heat).

In some embodiments, the base material may include hydrogen silsesquioxane (HSQ), methylsilsesquioxane (MSQ), porous polyarylether (PAE), porous SiLK, or porous silicon oxide (SiO₂). The decomposable porogen material may include an organic porogen compound that can provide porosity in the subsequent processes to the space previously occupied by the energy-removable material 135.

In some embodiments, the energy-removable material 135 may be formed using a deposition process followed by an etching process. The deposition process may include CVD, PVD, ALD, spin coating, or another suitable process, while the etching process may involve a reactive ion etching (RIE) process to remove the excess portions over the photoresist pattern 125.

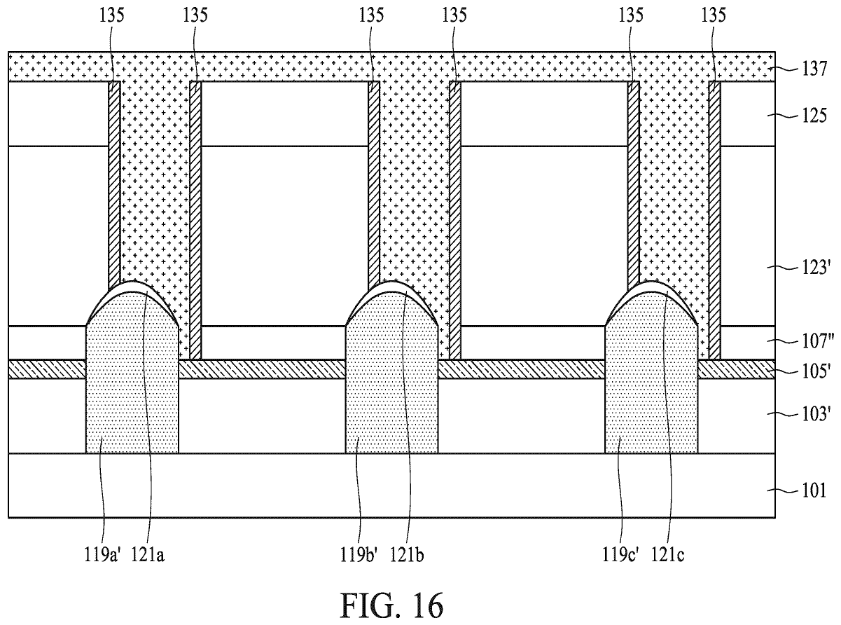

Next, in accordance with some embodiments, the openings 128′ and 130′ and the gaps 132′ may be filled with a metal layer 137, and the metal layer 137 may extend onto the photoresist pattern 125, as shown in FIG. 16. It should be noted that the metal layer 137 may be in direct contact with the first metal plugs 119a′, 119b′, and 119c′ as well as the etch stop layer 105′.

In some embodiments, the metal layer 137 may be made of copper (Cu). In some other embodiments, the metal layer 137 is made of tungsten (W), cobalt (Co), titanium (Ti), aluminum (Al), tantalum (Ta), or another applicable material. Moreover, in some embodiments, the metal layer 137 may be formed using a CVD process, a PVD process, an ALD process, a plating (e.g., electroplating) process, a sputtering process, or another suitable process.

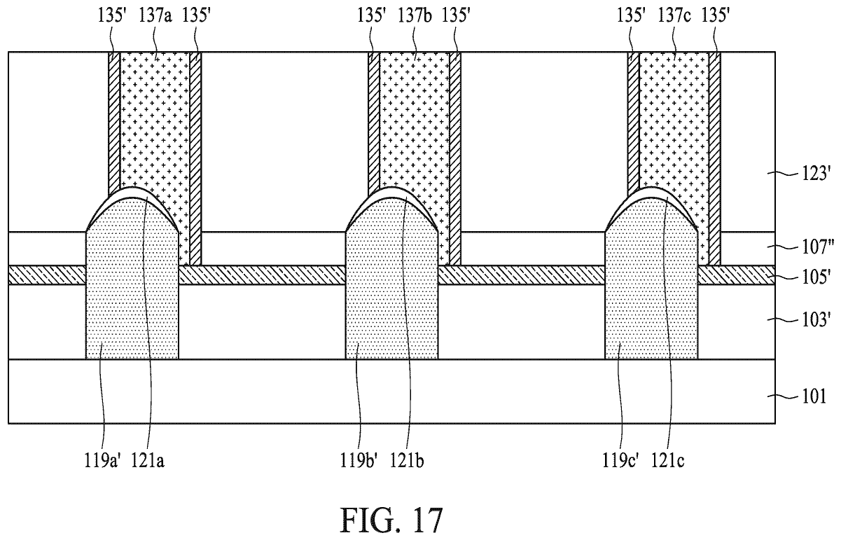

Next, in accordance with some embodiments, a planarization process may be performed to remove the photoresist pattern 125, as well as the excess portions of the metal layer 137 and the energy-removable material 135 above the third dielectric layer 123′, as shown in FIG. 17. The planarization process may involve a CMP process. After the planarization process, the second metal plugs 137a, 137b, 137c, along with the energy-removable layers 135′, are obtained. The respective step is illustrated as the step S19 in the method 10 shown in FIG. 4.

It should be noted that, in accordance with some embodiments of the present disclosure, the second metal plugs 137a, 137b, and 137c may be disposed over and may electrically connect to the first metal plugs 119a′, 119b′, and 119c′, respectively. The energy-removable layers 135′ may be located between the second metal plugs 137a, 137b, and 137c and the third dielectric layer 123′.

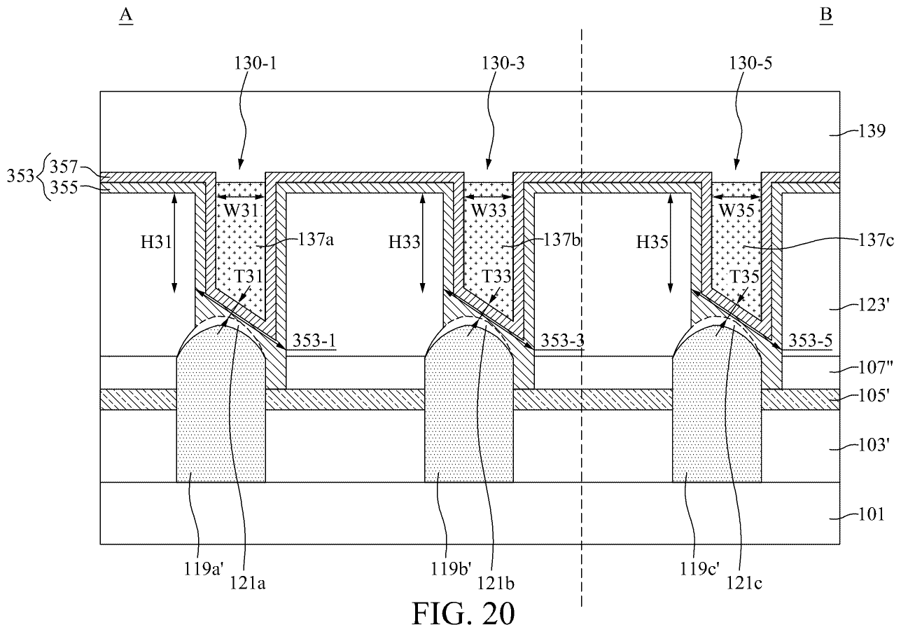

In an alternative embodiment, the second metal plugs 137a, 137b, and 137c may be formed in different regions, such as a pattern-dense region A and a pattern-sparse region B, surrounded by a lining layer 353. For example, as shown in FIG. 20, the second metal plugs 137a and 137b may be located in openings 130-1 and 130-3 within the pattern-dense region A, while the second metal plug 137c may be located in an opening 130-5 within the pattern-sparse region B. The openings 130-1, 130-3, and 130-5 formed in different regions may have different aspect ratios. For example, the openings 130-1 and 130-3 may have a same aspect ratio, while the openings 130-1 and 130-5 may have different aspect ratios. As a result, the second metal plugs 137a and 137b in the pattern-dense region A and the second metal plug 137c in the pattern-loose region B may have different aspect ratios.

For example, as shown in FIG. 20, a ratio of a height H31 of the second metal plug 137a to a width W31 of the second metal plug 137a may be equal to a ratio of a height H33 of the second metal plug 137b to a width W33 of the second metal plug 137b. In another example, the ratio of the height H31 of the second metal plug 137a to the width W31 may be less than or greater than a ratio of a height H35 of the second metal plug 137c to a width W35 of the second metal plug 137c.

The openings 130-1, 130-3, and 130-5 may be formed using processes similar to or same as those used for the openings 130 in FIG. 14, and repeated descriptions are omitted.

The lining layer 353 may be a multi-layered structure, consisting of a first sub-lining layer 355 and a second sub-lining layer 357 positioned over the first sub-lining layer 355. In some embodiments, the lining layer 353 extends from the pattern-dense region A to the pattern-sparse region B and includes a segment 353-1 deposited under the second metal plug 137a, a segment 353-3 under the second metal plug 137b, and a segment 353-5 under the second metal plug 137c. In addition, a thickness T31 of the segment 353-1 may be equal to a thickness T33 of the segment 353-3. In some embodiments, the thickness T31 of the segment 353-1 may be less than or greater than a thickness T35 of the second metal plug 137c.

The first sub-lining layer 355 of the lining layer 353 may be conformally deposited over the third dielectric layer 123′, covering sidewalls and bottom surfaces of the openings 130-1, 130-3, and 130-5, as well as the gaps 132 (see FIG. 14). In some embodiments, the first sub-lining layer 355 is in direct contact with the silicide layers 121a, 121b, and 121c, as well as the third dielectric layer 123′. The second sub-lining layer 357 of the lining layer 353 may be conformally deposited over the first sub-lining layer 355. In some embodiments, the lining layer 353 may be in direct contact with the second metal plugs 137a, 137b, and 137c.

The first sub-lining layer 355 and the second sub-lining layer 357 of the lining layer 353 are formed using deposition processes, such as CVD, PVD, ALD, MOCVD, sputtering, and plating. After the lining layer 353 is formed, remaining portions of the openings 130-1, 130-3, 130-5, and the gaps 132 are surrounded by the lining layer 353. It should be noted that, prior to the deposition of the first sub-lining layer 355 and the second sub-lining layer 357, a photoresist pattern (e.g., the photoresist pattern 125) used to define the openings 130-1, 130-3, and 130-5 is removed. In some embodiments, a planarization process is performed to remove the photoresist pattern (e.g., the photoresist pattern 125). In addition, after the deposition of the first sub-lining layer 355 and the second sub-lining layer 357, top surfaces of second metal plugs 137a, 137b, and 137c may be lower than a top surface of lining layer 353.

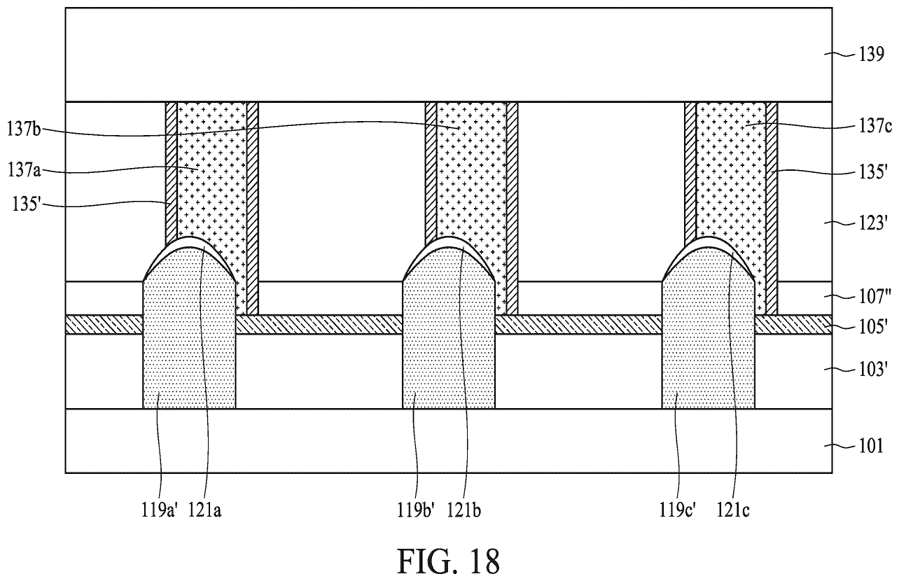

After the second metal plugs 137a, 137b, and 137c are formed, a fourth dielectric layer 139 is deposited, covering the third dielectric layer 123′, the energy-removable layers 135′, and the second metal plugs 137a, 137b, 137c, as shown in FIG. 18 in accordance with some embodiments. Some materials and processes used to form the fourth dielectric layer 139 are similar to, or same as, those used to form the first dielectric layer 103, and descriptions thereof are not repeated. In an alternative embodiment, the fourth dielectric layer 139 may be formed over the third dielectric layer 123′, the lining layer 353, and the second metal plugs 137a, 137b, and 137c, as shown in FIG. 20.

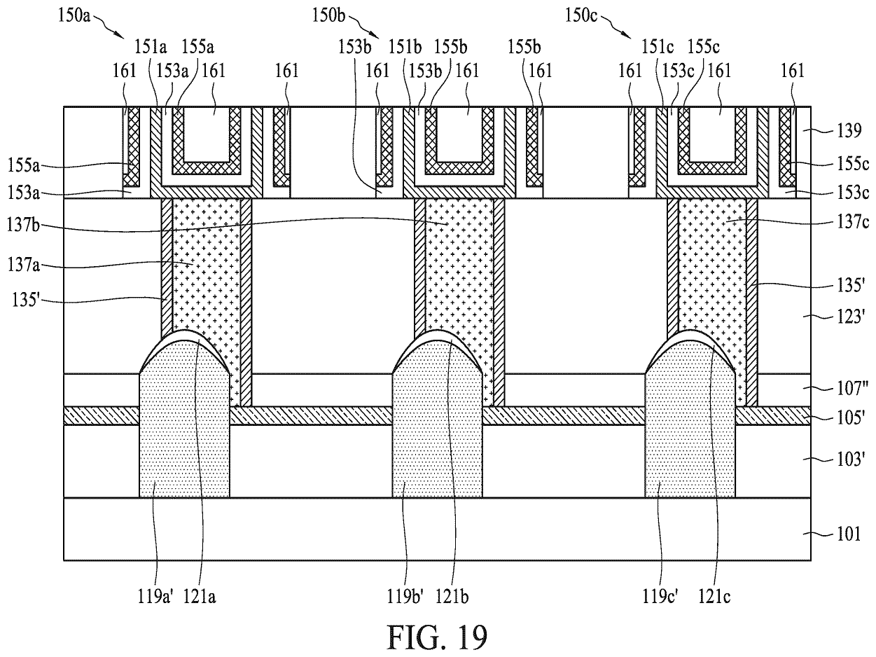

Referring to FIG. 19, in accordance with some embodiments of the present disclosure, the MIM capacitors 150a, 150b, and 150c may be formed within the fourth dielectric layer 139. In some embodiments, the metal layers 151a, 151b, 151c may have U-shaped profile, with the energy-removable layers 135′ and the second metal plugs 137a, 137b, and 137c covered by the corresponding metal layers 151a, 151b, and 151c. In addition, the metal layers 151a, 151b, and 151c are surrounded by the insulating layers 153a, 153b, and 153c, respectively, which are in turn surrounded by the metal layers 155a, 155b, and 155c. Furthermore, the remaining space within each of the MIM capacitors 150a, 150b, 150c may be filled with a filling dielectric layer 161.

Some materials and processes used to form the metal layers 151a, 151b, and 151c, as well as the metal layers 155a, 155b, and 155c, are similar to, or same as, those used to form the second metal plugs 137a, 137b, and 137c, and descriptions thereof are not repeated. Some materials and processes used to form the insulating layers 153a, 153b, and 153c, as well as the filling dielectric layer 161, are comparable to those used for the first dielectric layer 103, and descriptions thereof are not repeated. In some embodiments, the filling dielectric layer 161 and the fourth dielectric layer 139 may be made of a same material, resulting in no obvious interface between the filling dielectric layer 161 and the fourth dielectric layer 139.

After the MIM capacitors 150a, 150b, and 150c are formed, a heat treatment may be applied to remove the decomposable porogen material from the energy-removable layers 135′, generating pores that can be filled with air. This process results in the formation of air gaps 136a1, 136a2, 136b1, 136b2, 136c1, and 136c2 between the second metal plugs 137a, 137b, and 137c and the third dielectric layer 123′, as shown in FIG. 1.

In some embodiments, the heat treatment process can be replaced by a light treatment process, an e-beam treatment process, a combination thereof, or another applicable energy treatment process. For example, an ultraviolet (UV) light or laser light may be used to remove the decomposable porogen material from the energy-removable layers 135′, resulting in the formation of the air gaps 136a1, 136a2, 136b1, 136b2, 136c1, and 136c2.

As mentioned above, the relatively low dielectric constant of air can reduce a parasitic capacitance between the second metal plugs 137a, 137b, and 137c, thereby improving operation speed of the semiconductor device 100a. In some embodiments, the energy-removable layers 135′ and the air gaps 136a1, 136a2, 136b1, 136b2, 136c1, and 136c2 are not formed. In these cases, the second metal plugs 137a, 137b, and 137c may be in direct contact with the third dielectric layer 123′.

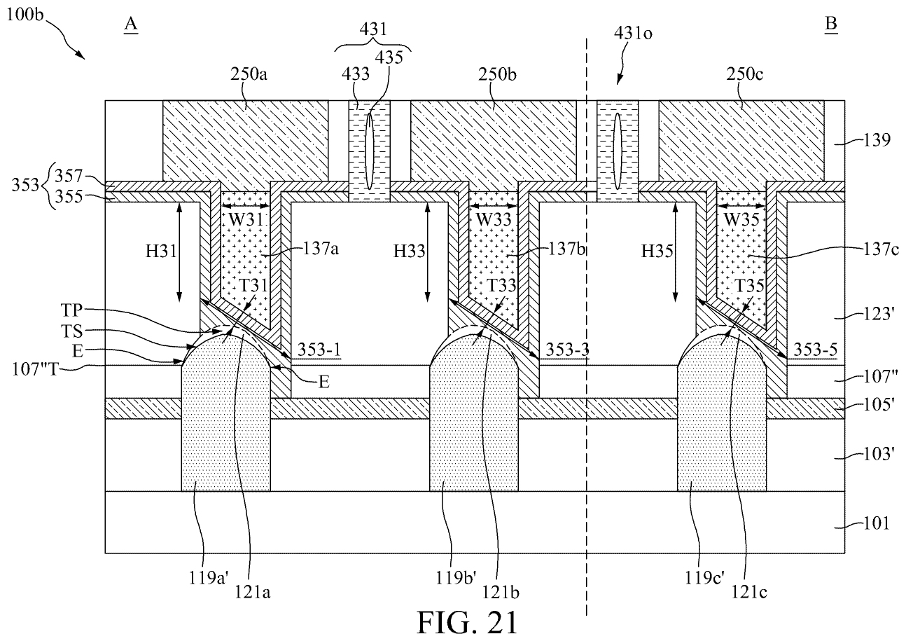

Referring to FIG. 21, in an alternative embodiment, the conductive features 250a, 250b, and 250c may be formed in the fourth dielectric layer 139. The conductive features 250a, 250b, and 250c may be disposed over the second metal plugs 137a, 137b, and 137c, respectively. In some embodiments, the conductive features 250a and 250b, which are located in the pattern-dense region A, may serve as bit lines. The conductive feature 250c, located in pattern-loose region B, may be a word line, a test point, a connection terminal, or another electrical connection line, such as a power or ground line. It should be noted that the conductive features 250a, 250b, and 250c are electrically connected to the first metal plugs 119a′, 119b′, and 119c′ through the second metal plugs 137a, 137b, and 137c, respectively. Some materials and processes used to form the bit lines 250a, 250b, 250c are similar to, or the same as, those used to form the second metal plugs 137a, 137b, and 137c, and descriptions thereof are not repeated.

After the bit lines 250a, 250b, 250c are formed, the liner structure 431 may be created in the fourth dielectric layer 139, positioned between the bit line 250a and the bit line 250b, as well as between the bit line 250b and the bit line 250c. In some embodiments, the liner structure 431 may penetrate through both the fourth dielectric layer 139 and the lining layer 353. The liner structure 431 may comprise an air gap 435 enclosed by a liner portion 433. With the inclusion of the liner structure 431 and the air gap 435, capacitive coupling between the conductive features can be reduced, and RC constant can be improved.

In some embodiments, the liner portion 433 may be made of or may include boron carbonitride (BCN). However, any other suitable dielectric materials may be utilized. In some embodiments, the air gap 435 may be sealed within the liner portion 433, meaning that the air gap 435 is not exposed.

The liner structure 431 may be formed by creating an opening 431O between the conductive feature 250a and the conductive feature 250b, as well as between the conductive feature 250b and the conductive feature 250c. The opening 431O may extend through both the fourth dielectric layer 139 and the lining layer 353. A bottom surface of the opening 431O may be coplanar with a top surface of the third dielectric layer 123′.

Next, a dielectric material for the liner portion 433 may be conformally deposited in the opening 431O and over the fourth dielectric layer 139 and the bit features 250a, 250b, and 250c. It should be noted that, during the deposition, a thickness of the dielectric material is adjusted to enclose an air gap (e.g., air gap 435) within the dielectric material. In some embodiments, the dielectric material may be made of or may include boron carbonitride (BCN), although any other suitable dielectric materials may be utilized. The deposition of the dielectric material may involve processes such as a CVD process, a PVD process, an ALD process, a spin-on coating process, or another suitable method. In some embodiments, the air gap 435 is sealed by the dielectric material within the opening 431O, meaning the air gap 435 is not exposed.

Next, the dielectric material may be partially removed to expose the fourth dielectric layer 139 and the conductive features 250a, 250b, and 250c, as shown in FIG. 21 in accordance with some embodiments. In some embodiments, the dielectric material may be partially removed using a planarization process, an etch-back process, or a combination thereof. The planarization process may include a chemical mechanical polishing (CMP) process. After the partial removal of the dielectric material, the semiconductor device 100b is obtained.

Embodiments of the semiconductor devices 100a, 100b and methods for manufacturing the same are provided. The semiconductor devices 100a and 100b include the first metal plugs 119a′, 119b′, and 119c′ and the second metal plugs 137a, 137b, and 137c positioned over the first metal plugs 119a′, 119b′, and 119c′. Because the first metal plugs 119a′, 119b′, and 119c′ have rounded (or curved) top surfaces TS, contact areas between the first metal plugs 119a′, 119b′, and 119c′ and the second metal plugs 137a, 137b, and 137c (or between the silicide layers 121a, 121b, and 121c and the second metal plugs 137a, 137b, and 137c) are increased compared to arrangements where the first metal plugs 119a′, 119b′, and 119c′ have flat top surfaces and the second metal plugs 137a, 137b, and 137c are perfectly aligned with the first metal plugs 119a′, 119b′, and 119c′. The increased contact areas of the rounded top surfaces TS may lead to a corresponding decrease in resistances between the first metal plugs 119a′, 119b′, and 119c′ and the second metal plugs 137a, 137b, and 137c, thereby improving overall device performance.

Moreover, the electric field strengths on the rounded top surfaces TS of the first metal plugs 119a′, 119b′, and 119c′ are evenly distributed, as the first metal plugs 119a′, 119b′, and 119c′ have no sharp portions. Therefore, the lifespan of the semiconductor devices 100a and 100b may be significantly extended, improving a performance and reliability of the devices.

In addition, because the etch stop layer 105′ adjoins sidewalls of the first metal plugs 119a′, 119b′, and 119c′, underlying electronic components are protected from exposure during the formation of the second metal plugs 137a, 137b, and 137c. This arrangement helps prevent or reduce issues caused by misalignment between the first metal plugs 119a′, 119b′, and 119c′ and the second metal plugs 137a, 137b, and 137c.

Furthermore, with the inclusion of the liner structure 431 and the air gap 435 in the semiconductor device 100b, capacitive coupling between the conductive features 250a, 250b, and 250c can be reduced, and the RC constant can be improved.

One aspect of the present disclosure provides a semiconductor device. The semiconductor device includes a substrate having a pattern-dense region and a pattern-sparse region; a first dielectric layer disposed over the semiconductor substrate; an etch stop layer disposed over the first dielectric layer; a second dielectric layer disposed over the etch stop layer; a first metal plug disposed penetrating through the second dielectric layer, the etch stop layer, and the first dielectric layer, wherein the first metal plug comprises a convex top surface; a third dielectric layer disposed covering the second dielectric layer and the convex top surface of the first metal plug; a lining layer disposed within the third dielectric layer, extending over the third dielectric layer, and covering the convex top surface of the first metal plug; a second metal plug disposed over the first metal plug and surrounded by the lining layer; a fourth dielectric layer disposed over the lining layer and the second metal plug; a first conductive feature and a second conductive feature disposed in the fourth dielectric layer and within the pattern-dense region of the substrate; and a third conductive feature disposed in the fourth dielectric layer and within the pattern-sparse region of the substrate. The first metal plug protrudes from the second dielectric layer.

Another aspect of the present disclosure provides a semiconductor device. The semiconductor device includes a substrate having a pattern-dense region and a pattern-sparse region; an etch stop layer disposed over the substrate; a first dielectric layer disposed over the etch stop layer; a first conductive plug and a second conductive plug disposed in the first dielectric layer. The first conductive plug and the second conductive plug comprise copper and are separated from the first dielectric layer by a first lining layer comprising manganese (Mn). The first conductive plug and the second conductive plug have different aspect ratios. The first lining layer extends from the pattern-dense region to the pattern-sparse region and includes a first segment deposited under the first conductive plug and a second segment deposited under the second conductive plug, the first segment of the first lining layer and the second segment of the first lining layer include different thicknesses.

Another aspect of the present disclosure provides a method for manufacturing a semiconductor device. The method includes providing a substrate having a pattern-dense region and a pattern-sparse region; forming a first dielectric layer over the semiconductor substrate; forming an etch stop layer over the first dielectric layer; forming a second dielectric layer over the etch stop layer; forming a first metal plug penetrating through the second dielectric layer, the etch stop layer and the first dielectric layer, wherein the first metal plug protrudes from the second dielectric layer and has a convex top surface; forming a third dielectric layer covering the second dielectric layer and the convex top surface of the etched first metal plug; forming a second metal plug over the first metal plug; forming a fourth dielectric layer over the third dielectric layer and covering the second metal plug; and forming a first conductive feature and a second conductive feature in the fourth dielectric layer and within the pattern-dense region of the substrate, and forming a third conductive feature in the fourth dielectric layer and within the pattern-sparse region of the substrate.

Another aspect of the present disclosure provides a method for manufacturing a semiconductor device. The method includes providing a substrate having a pattern-dense region and a pattern-sparse region; forming an etch stop layer over the substrate; forming a first dielectric layer over the etch stop layer; forming a first conductive plug in the first dielectric layer and within the pattern-dense region; and forming a second conductive plug in the first dielectric layer and within the pattern-sparse region.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A semiconductor device, comprising:
a substrate having a pattern-dense region and a pattern-sparse region;
an etch stop layer disposed over the substrate;
a first dielectric layer disposed over the etch stop layer; and
a first conductive plug and a second conductive plug disposed in the first dielectric layer;
wherein the first conductive plug and the second conductive plug comprise copper and are separated from the first dielectric layer by a first lining layer comprising manganese (Mn);
wherein the first conductive plug and the second conductive plug have different aspect ratios;
wherein the first lining layer extends from the pattern-dense region to the pattern-sparse region and includes a first segment deposited under the first conductive plug and a second segment deposited under the second conductive plug, the first segment of the first lining layer and the second segment of the first lining layer include different thicknesses; and
wherein the first conductive plug and the second conductive plug are surrounded by the first lining layer.

2. The semiconductor device of claim 1, wherein the first lining layer comprises a first sub-lining layer and a second sub-lining layer disposed over the first sub-lining layer.

3. The semiconductor device of claim 2, wherein the first sub-lining layer of the first lining layer includes manganese-rich manganese silicon (MnSi) or manganese (Mn), and the second sub-lining layer of the first lining layer includes copper manganese (CuMn).

4. The semiconductor device of claim 1, further comprising a second dielectric layer disposed over the first dielectric layer.

5. The semiconductor device of claim 4, further comprising:
a first conductive feature disposed in the second dielectric layer, over the first conductive plug, and within the pattern-dense region of the substrate; and
a second conductive feature disposed in the second dielectric layer, over the second conductive plug, and within the pattern-sparse region of the substrate.

6. The semiconductor device of claim 5, further comprising a liner structure disposed between the first conductive feature and the second conductive feature.

7. The semiconductor device of claim 6, wherein the liner structure penetrates through the second dielectric layer and the first lining layer.

8. The semiconductor device of claim 7, wherein the liner structure is separated from the first conductive feature and the second conductive feature by the second dielectric layer and the first lining layer.

9. The semiconductor device of claim 8, wherein the liner structure comprises an air gap enclosed by a liner portion of the liner structure.
